(19) United States
(12) Patent Application Publication
(10) Pub. No.: US 2017/0105278 A1
(43) Pub. Date: Apr. 13, 2017

(54) INTEGRATED HEAT SPREADER AND EMI SHIELD

(71) Applicant: GOOGLE INC., Mountain View, CA (US)

(72) Inventors: James Cooper, San Francisco, CA (US); Joshua Norman Lilje, San Jose, CA (US)

(21) Appl. No.: 14/881,915

(22) Filed: Oct. 13, 2015

(51) Int. Cl. H05K 1/02; H05K 3/32; H05K 3/30; H05K 1/18; H05K 1/11

(52) U.S. Cl. CPC H05K 1/0203; H05K 1/0216; H05K 1/181; H05K 1/111; H05K 3/303; H05K 3/321; H05K 2201/0323; H05K 2201/064; H05K 2201/0707

(57) ABSTRACT

An electronic device includes a printed circuit board (PCB), the PCB including at least one grounding pad, an integrated circuit mounted on the PCB; an electrically-conductive frame mounted on the PCB and surrounding the integrated circuit, the frame being electrically connected to the at least one grounding pad, and a flexible electrically-conductive, high-thermal-conductivity heat spreader in electrical contact with the frame and in thermal contact with the integrated circuit. The frame, the heat spreader, and the at least one grounding pad form an EMI shield that reduces EMI leakage from the integrated circuit outside a volume defined by the frame, the heat spreader, and the at least one grounding pad.

### BACKGROUND

As electronic devices (e.g., phones, tablets, laptop computers) have evolved, they have become thinner, but thinner products have a limited amount of vertical space to house components within the device. Electrical components, including integrated circuits, within electronic devices can emit electrical noise, also known as electro-magnetic interference (EMI), and shields can be placed over such electrical components to reduce EMI to which other components, within and outside electronic device, are exposed. Electrical components also generate heat by dissipating power, which can limit the performance of the components, and therefore silicone-based thermal pads can be placed between the electrical components and the EMI shield to transfer the power from the electrical components to the EMI shield with a smaller temperature change. To remove heat from the assembly, a heat spreader can be placed on top of the EMI shield to transfer the heat away from the electrical components. However, all of these parts take up space within the device, especially in the vertical direction, which can serve to limit the thinness of the device. Thus, a need exists to create a thinner stack of components within electronic devices.

In addition, a common functional test for an electronic device is to drop a ball on the device in order to simulate real world usage. The goal of the test is to ensure nothing breaks in the device when the ball is dropped on the exterior of the device. Electronic components (e.g., central processing units (CPUs)) are fragile, and when enough load is applied to the exterior housing of the device, electronic components within the device can be damaged. Thus, a larger air gap in the device between the fragile electronic components of the device and the housing of the device could prevent the fragile electronic components from being damage when the housing suffers an impact. However, a larger air gap demands thinner stacks of components within the device, for a device of constant thickness.

### SUMMARY

In a general aspect, an electronic device includes a printed circuit board (PCB), the PCB including at least one grounding pad, an integrated circuit mounted on the PCB; an electrically-conductive frame mounted on the PCB and surrounding the integrated circuit, the frame being electrically connected to the at least one grounding pad, and a flexible electrically-conductive, high-thermal-conductivity heat spreader in electrical contact with the frame and in thermal contact with the integrated circuit. The frame, the heat spreader, and the at least one grounding pad form an EMI shield that reduces EMI leakage from the integrated circuit outside a volume defined by the frame, the heat spreader, and the at least one grounding pad.

Implementations include one or more of the following features. For example, the heat spreader can be secured to the frame with an electrically conductive adhesive material. The heat spreader can have a thickness of less than 100 μm or less than 75 μm. The heat spreader can include graphite, or a metal material. The heat spreader can be removably secured to the frame. The heat spreader can extend laterally beyond the frame. A portion of the heat spreader that extends laterally beyond the frame can be in thermal contact with a heat pipe that conducts heat away from the integrated circuit. The integrated circuit can include a central processing unit of the electronic device.

In another general aspect, a method can include mounting an integrated circuit on printed circuit board (PCB), the PCB including at least one grounding pad, and having an electrically-conductive frame mounted on the PCB and surrounding a location at which the integrated circuit in mounted, where the frame is electrically connected to the at least one grounding pad. A flexible electrically-conductive, high-thermal-conductivity heat spreader can be installed in electrical contact with the frame and in thermal contact with the integrated circuit, where the frame, the heat spreader, and the at least one grounding pad form an EMI shield that reduces EMI leakage from the integrated circuit outside a volume defined by the frame, the heat spreader, and the at least one grounding pad.

Implementations include one or more of the following features. For example, installing the heat spreader can include securing the heat spreader to the frame with an electrically conductive adhesive material. The heat spreader can have a thickness of less than 100 μm or less than 75 μm. The heat spreader can includes graphite and can include a metal material. The heat spreader can include removably securing the heat spreader to the frame, and installing the heat spreader can includes thermally connecting a portion of the heat spreader that extends laterally beyond the frame to a heat pipe that conducts heat away from the integrated circuit. The integrated circuit can include a central processing unit of the electronic device. Installing the heat spreader can include pressing a portion of the heat spreader located within the frame into thermal contact with the integrated circuit.

The details of one or more implementations are set forth in the accompanying drawings and the description below. Other features will be apparent from the description and drawings, and from the claims.

### BRIEF DESCRIPTION OF DRAWINGS

FIG. 1 is a schematic side view of a portion of an electronic device in accordance with the disclosed subject matter.

FIG. 2 is a schematic top view of a portion of an electronic device in accordance with the disclosed subject matter.

FIG. 3 is a schematic side view of a portion of an electronic device in accordance with the disclosed subject matter.

FIG. 4 is a schematic side view of a portion of an electronic device in accordance with the disclosed subject matter.

FIG. 5 illustrates a flow diagram of an example process for installing an electrically-conductive, single-sheet heat spreader, in accordance with disclosed implementations.

FIG. 6 shows an example of a computer device and a mobile computer device that can be used to implement the techniques described here.

Like reference symbols in the various drawings indicate like elements.

### DETAILED DESCRIPTION

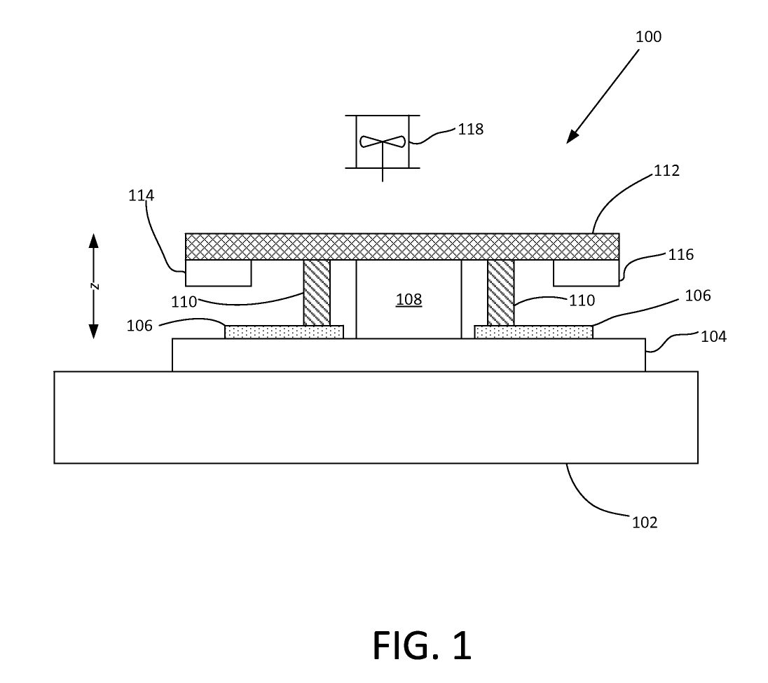

FIG. 1 is a schematic side view of a portion of an electronic device 100. The electronic device 100 includes a housing 102. For example, the housing 102 can include the exterior housing of a laptop computer, a mobile phone, a tablet computer, etc. The housing 102 can be connected to a printed circuit board 104. In some implementations, the printed circuit board 104 is directly connected to the housing 102. In some implementations, the printed circuit board 104 is connected to one or more intermediate members (not shown) that, in turn, are connected to the housing 102. The printed circuit board 104 can include a plurality of conductive electrical traces that can electrically connect different components, and/or different elements of the same component, that are mounted on the printed circuit board 104. One or more of the electrical traces can be held at a ground potential and can serve as a grounding pad 106 that acts as a plane held at a grounded electrical potential within the electronic device 100.

An integrated circuit 108 (e.g., a central processing unit, a graphics processor, etc.) can be mounted on the printed circuit board 104, above the grounding pad 106. When operated within the electronic device 100, the integrated circuit 108 can produce a significant amount of heat or power dissipation and also can be a source of EMI. To reduce the amount of EMI that is radiated from the integrated circuit 108 or other components to/from other components within the electronic device 100 and that is radiated outside the electronic device 100, an electrically conductive enclosure (also known as a Faraday cage) can exist around the integrated circuit or other components.

The electrically conductive enclosure can be defined by the grounding pad 106, a frame 110 that surrounds a perimeter of the integrated circuit 108 and an electrically conductive and thermally conductive heat spreader 112. The frame 110 can be secured to the grounding pad 106 in a variety of different ways. For example, the frame 110 can be soldered or brazed to the grounding pad 106, can be mechanically secured (e.g., by bolts, screws, rivets, snap-fit members, etc.) to the grounding pad 106, or can be adhered to the grounding pad 106 with an electrically-conducting adhesive material. The heat spreader 112 also can be secured to the frame 110 in a variety of different ways. For example, the heat spreader 112 can be soldered or brazed to the frame 110, can be mechanically secured (e.g., by bolts, screws, rivets, snap-fit members, etc.) to the frame 110, or can be adhered to the frame 110 with an electrically-conducting adhesive material.

The heat spreader 112 can include a variety of different materials. In one implementation, the heat spreader 112 can include graphite or graphene. In another implementation, the heat spreader 112 can include metal (e.g., copper, aluminum, silver, or other metals, including alloys). The heat spreader 112 can be electrically conductive. For example, the electrical conductivity of the heat spreader 112 can be greater than about 5×10⁴ siemens per meter (S/m). In the case of graphite, and other materials that have different conductivities parallel to, and perpendicular to, their basal planes, the electrical conductivity of the heat spreader 112 can be greater than 5×10⁴ siemens per meter (S/m) in a direction parallel to the basal plane. The heat spreader 112 also can be thermally conductive. For example, the thermal conductivity of the heat spreader 112 can be greater than 25 W per meter per Kelvin (W/m/K) at room temperature. In the case of graphite, and other materials that have different conductivities parallel to, and perpendicular to, their basal planes, the thermal conductivity of the heat spreader 112 can be greater than 25 W per meter per Kelvin (W/m/K) at room temperature in a direction parallel to the basal plane.

The heat spreader 112 also can be relatively pliant, so it can be placed into good thermal and electrical contact with the frame 110 and the top surface of the integrated circuit 108 and so that it can conform to the shape of the frame and the integrated circuit. For example, the heat spreader 112 can include a material that is easily formable with a person's hands (e.g., a material that can have a bend radius under 10 mm without breaking and that can be formed into the desired shape with under 30 N of force). In addition, the thermal and electrical conductivities of the connections between the heat spreader 112 and the integrated circuit 108 and between the heat spreader 112 and the frame 110 also can be relatively high, so that heat can be transferred from the integrated circuit and so that the heat spreader, the frame 110 and the grounding pad 106 can form an effective electrically conductive enclosure to limit EMI leakage. In some implementations, thermal grease can be placed between the integrated circuit 108 and the spreader 112 to facilitate the transfer of heat from the integrated circuit to the heat spreader. In some implementations, electrically-conductive adhesive can be used to join the heat spreader 112 to the frame 110.

The heat spreader 112 can extend laterally outward from the frame 110, so that heat can be transferred through the heat spreader 112 to the periphery of the heat spreader and away from the integrated circuit 108. The heat spreader 112 can be thermally connected to one or more heat pipes 114, 116 that can transfer heat away from the heat spreader 112 to other regions of the electrical device 100. For example, a portion of the heat pipe 114, 116 can be connected to a housing of the electrical device, so that heat generated by the integrated circuit 108 can be transferred to the heat spreader 112, and then to the heat pipe 114, 116, and then to the housing, where it is transferred to the external environment. In some implementations, the electronic device 100 can include a fan 118 that can blow air onto warm components of the device, including the heat spreader 112, the frame 110, the heat pipes 114, 116, and, in some implementations, the integrated circuit 108 (e.g., when the frame and/or the heat spreader heat spreader includes openings through which air can flow).

By using an electrically-conductive heat spreader 112, a single sheet of material can be used to both transfer heat away from the integrated circuit 108 and to shield EMI emission from the integrated circuit. The thickness of the heat spreader 112 can be, for example, less than 200 μm, less than 100 μm, less than 75 μm, or less than 50 μm. Therefore, using a single sheet of material for the electrically-conductive heat spreader 112 can result in the height, z, of the EMI-shielded and thermally controlled integrated circuit above the printed circuit board 104 being less than about 1.3 mm when the integrated circuit is a central processing unit of the electronic device 100.

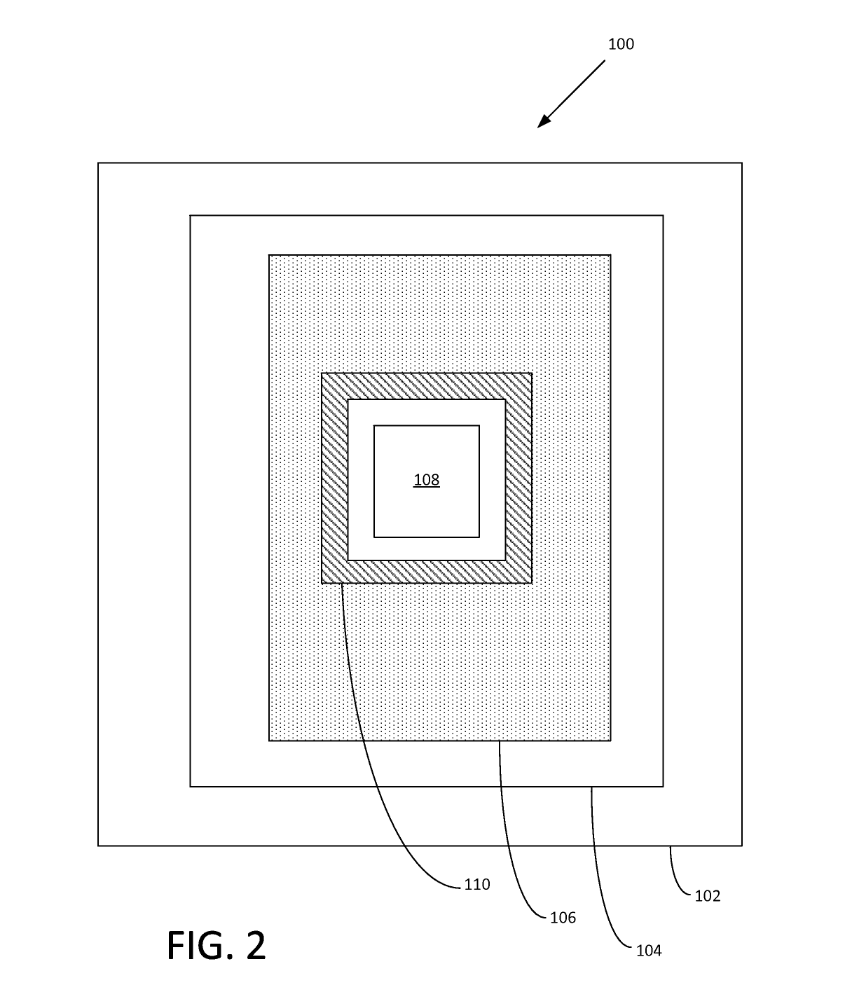

FIG. 2 is a schematic top view of a portion of the electronic device 100 in accordance with the disclosed subject matter. The electronic device 100 can include a housing 102 that is coupled to the printed circuit board 104. The printed circuit board 104 can have disposed on it one or more electrical traces that form the grounding pad 106. The integrated circuit 108 can be mounted on the printed circuit board 104, and the electrically-conducting frame 110 also can be mounted on the printed circuit board 104 and can surround the integrated circuit 108.

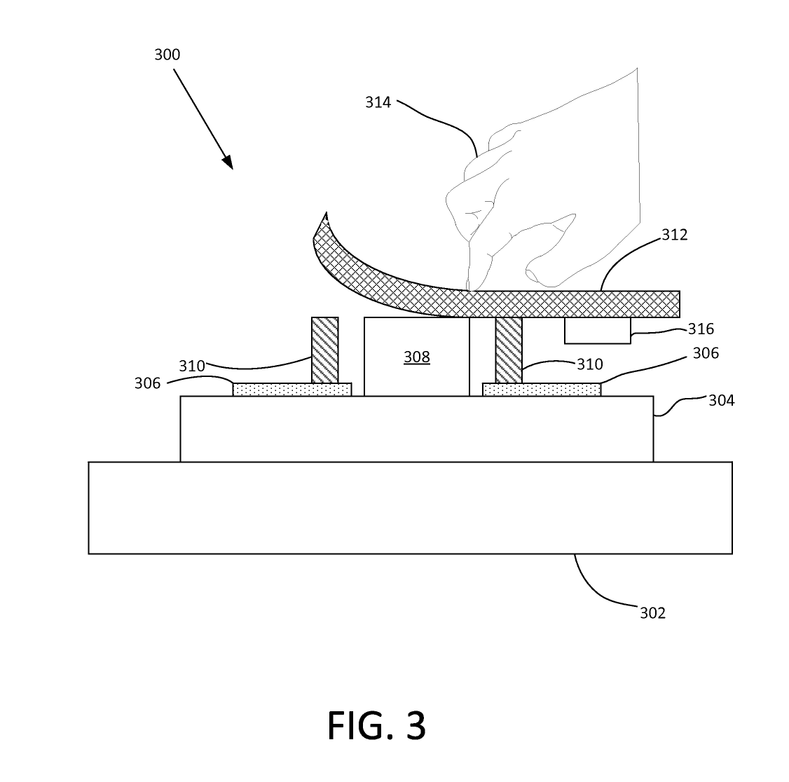

FIG. 3 is a schematic side view of a portion of an electronic device 300 in accordance with the disclosed subject matter. The electronic device 300 can include a portion of a housing 302 that can be connected to a printed circuit board 304. The printed circuit board 304 can have disposed on it one or more electrical traces that form a grounding pad 306. An integrated circuit 308 can be mounted on the printed circuit board 304, and the frame 310 also can be mounted on the printed circuit board 304 and can surround the perimeter of the integrated circuit 308.

A single sheet, electrically-conductive, heat spreader can be electrically connected to the frame 310 and thermally connected to the integrated circuit 308 to create a Faraday cage around the integrated circuit to limit EMI leakage from the integrated circuit and to efficiently transfer heat away from the integrated circuit. In some implementations, the heat spreader 312 can be thermally connected to a heat pipe 316.

In some implementations, the heat spreader 312 can be a thin sheet of material (e.g., a tape or a foil) and can have a thickness of less than, for example, 200 μm, 100 μm, or 50 μm. In some implementations, the heat spreader 312 can be placed into electrical contact with the frame 310 and can be placed into thermal contact with the integrated circuit 308 by pressing the heat spreader 312 down onto the frame 310 and the integrated circuit 308. For example, a technician 314 can press the heat spreader 312 into good electrical contact with the frame 310 and into good thermal contact with the integrated circuit 308. In some implementations, a robotic process can be used to press the heat spreader 312 into electrical contact with the frame 310 and into thermal contact with the circuit 308. In some implementations, electrically-conductive adhesive can be used to join the heat spreader 312 to the frame 310. In some implementations, the heat spreader 312 can extend laterally away from the integrated circuit 308 beyond the edge of the frame 310. In some implementations, the heat spreader 312 can be removably joined to the frame 310 and the integrated circuit 308. Then, to access the integrated circuit (e.g., to remove and replace the integrated circuit), the heat spreader can be easily removed from the frame 310 and the integrated circuit 308. In some implementations, the heat spreader 312 can be removed by grasping and lifting a portion of the heat spreader that extends beyond the perimeter of the frame 310 to lift the heat spreader 312 up and away from the frame 310.

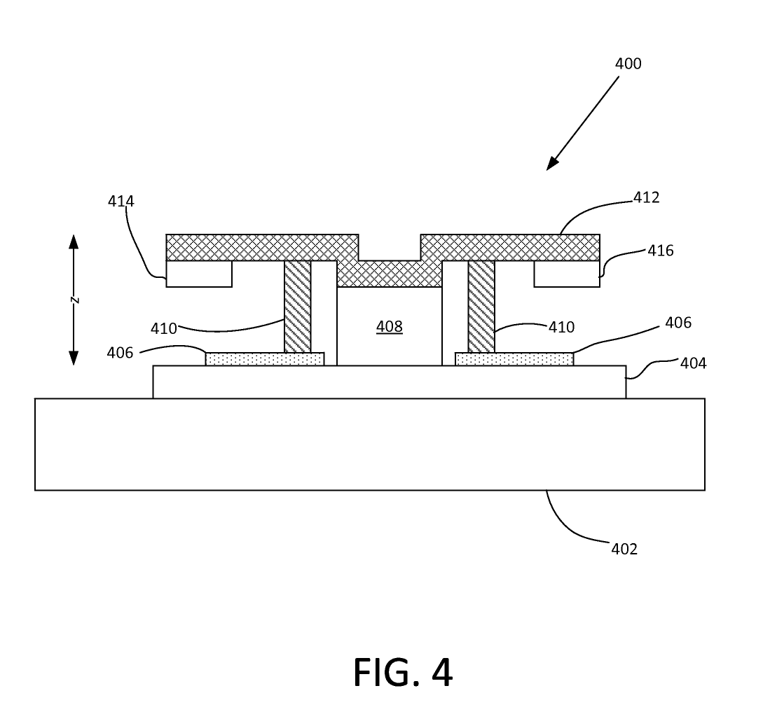

FIG. 4 is a schematic side view of a portion of an electronic device 400 in accordance with the disclosed subject matter. The electronic device 400 includes a housing 402 that may include the exterior housing of a laptop computer, a mobile phone, a tablet computer, etc. The housing 402 can be connected to a printed circuit board 404. The printed circuit board 404 can include a plurality of conductive electrical traces that can electrically connect different components, and/or different elements of the same component, that are mounted on the printed circuit board 404. One or more of the electrical traces can be held at a ground potential and can serve as a grounding pad 406 that acts as a plane held at a grounded electrical potential within the electronic device 400.

An integrated circuit 408 (e.g., a central processing unit, a graphics processor, etc.) can be mounted on the printed circuit board 404, above the grounding pad 406. An electrically conductive enclosure can be defined by the grounding pad 406, a frame 410 that surrounds a perimeter of the integrated circuit 408 and an electrically conductive and thermally conductive heat spreader 412. The frame 410 can be secured to the grounding pad 406, and the heat spreader 412 also can be secured to the frame 410 in a variety of different ways, as described above.

The heat spreader 412 can include a variety of different materials. In one implementation, the heat spreader 412 can include graphite or graphene. In another implementation, the heat spreader 412 can include metal (e.g., copper, aluminum, silver, or other metals, including alloys). The heat spreader 412 can be electrically conductive. For example, the electrical conductivity of the heat spreader 412 can be greater than about 5×10⁴ siemens per meter (S/m). In the case of graphite, and other materials that have different conductivities parallel to, and perpendicular to, their basal planes, the conductivity of the heat spreader 412 can be greater than 5×10⁴ siemens per meter (S/m) in a direction parallel to the basal plane. The heat spreader 412 also can be thermally conductive. For example, the thermal conductivity of the heat spreader 412 can be greater than 25 W per meter per Kelvin (W/m/K) at room temperature. The heat spreader 412 also can be relatively pliant, so it can be placed into good thermal and electrical contact with the frame 410 and the top surface of the integrated circuit 408 and that it can conform to the shape of the frame and the integrated circuit. In addition, the thermal and electrical conductivities of the connections between the heat spreader 412 and the integrated circuit 408 and between the heat spreader 412 and the frame 410 also can be relatively high, so that heat can be transferred from the integrated circuit and so that the heat spreader, the frame 410 and the grounding pad 406 can form an effective electrically conductive enclosure to limit EMI leakage. In some implementations, thermal grease can be placed between the integrated circuit 408 and the spreader 412 to facilitate the transfer of heat from the integrated circuit to the heat spreader. In some implementations, electrically-conductive adhesive can be used to join the heat spreader 412 to the frame 410.

The heat spreader 412 can extend laterally outward from the frame 410, so that heat can be transferred through the heat spreader 412 to the periphery of the heat spreader and away from the integrated circuit 408. The heat spreader 412 can be thermally connected to one or more heat pipes 414, 416 that can transfer heat away from the heat spreader 412 two other regions of the electrical device 400. For example, a portion of the heat pipe 414, 416 can be connected to a housing of the electrical device, so that heat generated by the integrated circuit 408 can be transferred to the heat spreader 412, and then to the heat pipe 414, 416, and then to the housing, where it is transferred to the external environment.

By using an electrically-conductive heat spreader 412, a single sheet of material can be used to both transfer heat away from the integrated circuit 408 and to shield EMI emission from the integrated circuit. The heat spreader 412 need not be located in a plane, but rather can be arranged in a shape that conforms to the profile of the integrated circuit 408, the frame 410, and the heat pipes 414, 416 (if they are used). Thus, if the height of the frame 410 above the printed circuit board 404 is higher or lower than the height of the integrated circuit 408, the heat spreader 412 can easily conform to the difference in heights. For example, when the heat spreader is provided in the form of a foil or tape, the heat spreader 412 can be easily pressed into contact with the frame 410 and the top surface of the integrated circuit 408. The thickness of the heat spreader 412 can be, for example, less than 200 μm, less than 100 μm, less than 75 μm, or less than 50 μm. Therefore, using a single sheet of material for the electrically-conductive heat spreader 412 can result in the height, z, of the EMI-shielded and thermally controlled integrated circuit above the printed circuit board 404 being less than about 1.3 mm when the integrated circuit is a central processing unit of the electronic device 400.

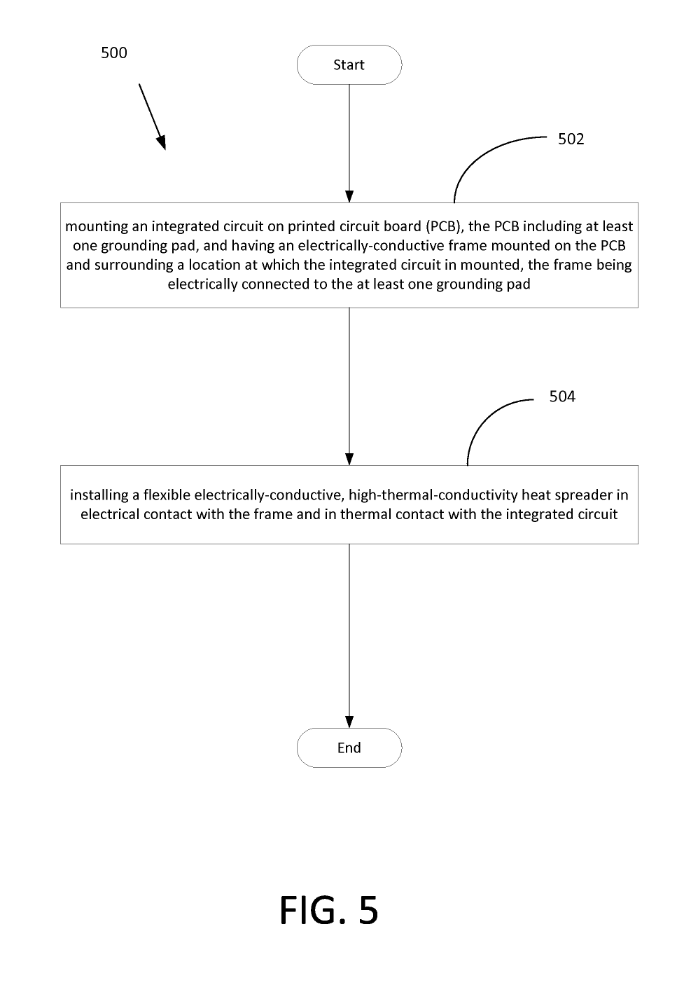

FIG. 5 illustrates a flow diagram (500) of an example process for installing an electrically-conductive, single-sheet heat spreader on an integrated circuit, in accordance with disclosed implementations. The integrated circuit can be mounted on a printed circuit board, where the printed circuit board includes at least one grounding and has an electrically-conductive frame mounted on the printed circuit board, where the frame surrounds the location at which the integrated circuit is mounted and is electrically connected to the grounding (502). A flexible electrically-conductive, high-thermal-conductivity heat spreader is installed in electrical contact with the frame and in thermal contact with the integrated circuit (504). The frame, the heat spreader, and the grounding pad form and EMI shield that reduces EMI leakage from the integrated circuit outside a volume defined by the frame, heat spreader. Installing the heat spreader can include thermally connecting a portion of the heat spreader that extends laterally beyond the frame to a heat pipe that conducts heat away from the integrated circuit. Installing the heat spreader can include pressing a portion of the heat spreader located within the frame into thermal contact with the integrated circuit.

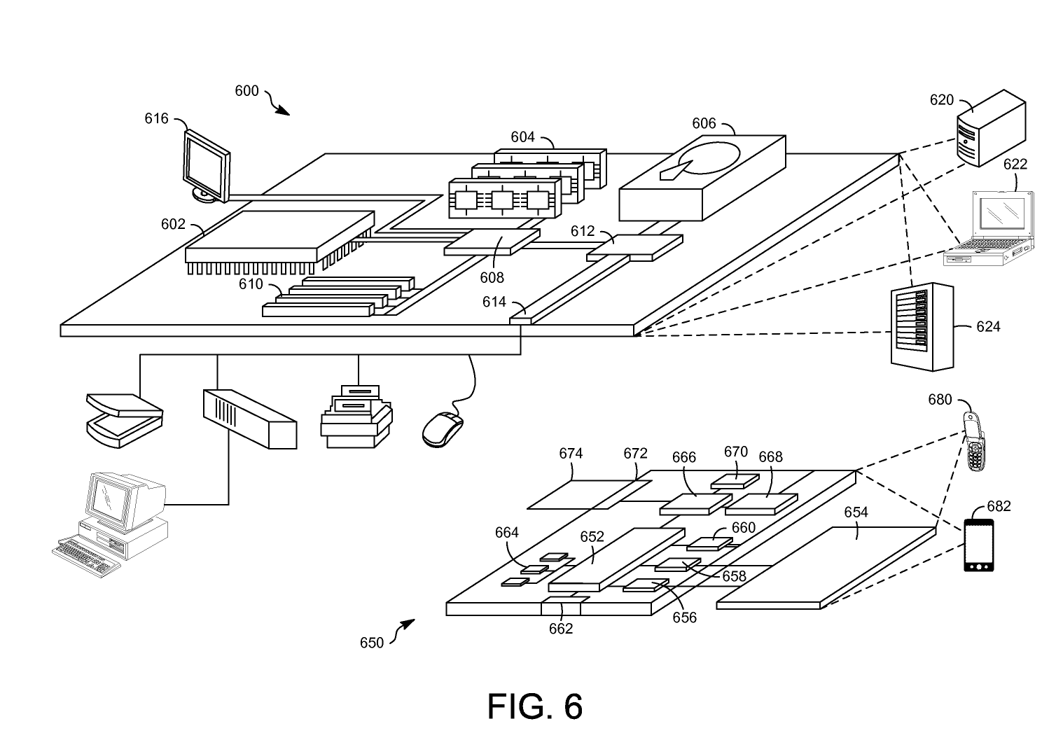

FIG. 6 shows an example of a generic computer device 600 and a generic mobile computer device 650, which may be used with the techniques described here. Computing device 600 is intended to represent various forms of digital computers, such as laptops, desktops, tablets, workstations, personal digital assistants, televisions, servers, blade servers, mainframes, and other appropriate computing devices. Computing device 650 is intended to represent various forms of mobile devices, such as personal digital assistants, cellular telephones, smart phones, and other similar computing devices. The components shown here, their connections and relationships, and their functions, are meant to be exemplary only, and are not meant to limit implementations of the inventions described and/or claimed in this document.

Computing device 600 includes a processor 602, memory 604, a storage device 606, a high-speed interface 608 connecting to memory 604 and high-speed expansion ports 610, and a low speed interface 612 connecting to low speed bus 614 and storage device 606. The processor 602 can be a semiconductor-based processor. The memory 604 can be a semiconductor-based memory. Each of the components 602, 604, 606, 608, 610, and 612, are interconnected using various busses, and may be mounted on a common motherboard or in other manners as appropriate. The processor 602 can process instructions for execution within the computing device 600, including instructions stored in the memory 604 or on the storage device 606 to display graphical information for a GUI on an external input/output device, such as display 616 coupled to high speed interface 608. In other implementations, multiple processors and/or multiple buses may be used, as appropriate, along with multiple memories and types of memory. Also, multiple computing devices 600 may be connected, with each device providing portions of the necessary operations (e.g., as a server bank, a group of blade servers, or a multi-processor system).

The memory 604 stores information within the computing device 600. In one implementation, the memory 604 is a volatile memory unit or units. In another implementation, the memory 604 is a non-volatile memory unit or units. The memory 604 may also be another form of computer-readable medium, such as a magnetic or optical disk.

The storage device 606 is capable of providing mass storage for the computing device 600. In one implementation, the storage device 606 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 604, the storage device 606, or memory on processor 602.

The high speed controller 608 manages bandwidth-intensive operations for the computing device 600, while the low speed controller 612 manages lower bandwidth-intensive operations. Such allocation of functions is exemplary only. In one implementation, the high-speed controller 608 is coupled to memory 604, display 616 (e.g., through a graphics processor or accelerator), and to high-speed expansion ports 610, which may accept various expansion cards (not shown). In the implementation, low-speed controller 612 is coupled to storage device 606 and low-speed expansion port 614. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 600 may be implemented in a number of different forms, as shown in the figure. For example, it may be implemented as a standard server 620, or multiple times in a group of such servers. It may also be implemented as part of a rack server system 624. In addition, it may be implemented in a personal computer such as a laptop computer 622. Alternatively, components from computing device 600 may be combined with other components in a mobile device (not shown), such as device 650. Each of such devices may contain one or more of computing device 600, 650, and an entire system may be made up of multiple computing devices 600, 650 communicating with each other.

Computing device 650 includes a processor 652, memory 664, an input/output device such as a display 654, a communication interface 666, and a transceiver 668, among other components. The device 650 may also be provided with a storage device, such as a microdrive or other device, to provide additional storage. Each of the components 650, 652, 664, 654, 666, and 668, are interconnected using various buses, and several of the components may be mounted on a common motherboard or in other manners as appropriate.

The processor 652 can execute instructions within the computing device 650, including instructions stored in the memory 664. The processor may be implemented as a chipset of chips that include separate and multiple analog and digital processors. The processor may provide, for example, for coordination of the other components of the device 650, such as control of user interfaces, applications run by device 650, and wireless communication by device 650.

Processor 652 may communicate with a user through control interface 658 and display interface 656 coupled to a display 654. The display 654 may be, for example, a TFT LCD (Thin-Film-Transistor Liquid Crystal Display) or an OLED (Organic Light Emitting Diode) display, or other appropriate display technology. The display interface 656 may comprise appropriate circuitry for driving the display 654 to present graphical and other information to a user. The control interface 658 may receive commands from a user and convert them for submission to the processor 652. In addition, an external interface 662 may be provide in communication with processor 652, so as to enable near area communication of device 650 with other devices. External interface 662 may provide, for example, for wired communication in some implementations, or for wireless communication in other implementations, and multiple interfaces may also be used.

The memory 664 stores information within the computing device 650. The memory 664 can be implemented as one or more of a computer-readable medium or media, a volatile memory unit or units, or a non-volatile memory unit or units. Expansion memory 674 may also be provided and connected to device 650 through expansion interface 672, which may include, for example, a SIMM (Single In Line Memory Module) card interface. Such expansion memory 674 may provide extra storage space for device 650, or may also store applications or other information for device 650. Specifically, expansion memory 674 may include instructions to carry out or supplement the processes described above, and may include secure information also. Thus, for example, expansion memory 674 may be provide as a security module for device 650, and may be programmed with instructions that permit secure use of device 650. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 664, expansion memory 674, or memory on processor 652, that may be received, for example, over transceiver 668 or external interface 662.

Device 650 may communicate wirelessly through communication interface 666, which may include digital signal processing circuitry where necessary. Communication interface 666 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 668. In addition, short-range communication may occur, such as using a Bluetooth, WiFi, or other such transceiver (not shown). In addition, GPS (Global Positioning System) receiver module 670 may provide additional navigation- and location-related wireless data to device 650, which may be used as appropriate by applications running on device 650.

Device 650 may also communicate audibly using audio codec 660, which may receive spoken information from a user and convert it to usable digital information. Audio codec 660 may likewise generate audible sound for a user, such as through a speaker, e.g., in a handset of device 650. Such sound may include sound from voice telephone calls, may include recorded sound (e.g., voice messages, music files, etc.) and may also include sound generated by applications operating on device 650.

The computing device 650 may be implemented in a number of different forms, as shown in the figure. For example, it may be implemented as a cellular telephone 680. It may also be implemented as part of a smart phone 682, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

A number of embodiments have been described. Nevertheless, it will be understood that various modifications may be made without departing from the spirit and scope of the invention.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

What is claimed is:

1. An electronic device comprising:
a printed circuit board (PCB), the PCB including at least one grounding pad;
an integrated circuit mounted on the PCB;
an electrically-conductive frame mounted on the PCB and surrounding the integrated circuit, the frame being electrically connected to the at least one grounding pad; and
a flexible electrically-conductive, high-thermal-conductivity heat spreader in electrical contact with the frame and in thermal contact with the integrated circuit,
wherein the frame, the heat spreader, and the at least one grounding pad form an EMI shield that reduces EMI leakage from the integrated circuit outside a volume defined by the frame, the heat spreader, and the at least one grounding pad.

2. The electronic device of claim 1, wherein the heat spreader is secured to the frame with an electrically conductive adhesive material.

3. The electronic device of claim 1, wherein the heat spreader has a thickness of less than 100 μm.

4. The electronic device of claim 1, wherein the heat spreader has a thickness of less than 75 μm.

5. The electronic device of claim 1, wherein the heat spreader includes graphite.

6. The electronic device of claim 1, wherein the frame includes a metal material.

7. The electronic device of claim 1, wherein the heat spreader is removably secured to the frame.

8. The electronic device of claim 1, wherein a portion of the heat spreader extends laterally beyond the frame.

9. The electronic device of claim 7, wherein a portion of the heat spreader that extends laterally beyond the frame is in thermal contact with a heat pipe that conducts heat away from the integrated circuit.

10. The electronic device of claim 1, wherein the integrated circuit includes a central processing unit of the electronic device.

11. A method comprising:
mounting an integrated circuit on printed circuit board (PCB), the PCB including at least one grounding pad, and having an electrically-conductive frame mounted on the PCB and surrounding a location at which the integrated circuit in mounted, the frame being electrically connected to the at least one grounding pad; and
installing a flexible electrically-conductive, high-thermal-conductivity heat spreader in electrical contact with the frame and in thermal contact with the integrated circuit,
wherein the frame, the heat spreader, and the at least one grounding pad form an EMI shield that reduces EMI leakage from the integrated circuit outside a volume defined by the frame, the heat spreader, and the at least one grounding pad.

12. The method of claim 11, wherein installing the heat spreader includes securing the heat spreader to the frame with an electrically conductive adhesive material.

13. The method of claim 11, wherein the heat spreader has a thickness of less than 100 μm.

14. The method of claim 11, wherein the heat spreader has a thickness of less than 75 μm.

15. The method of claim 11, wherein the heat spreader includes graphite.

16. The method of claim 11, wherein the frame includes a metal material.

17. The method of claim 11, wherein installing the heat spreader includes removably securing the heat spreader to the frame.

18. The method of claim 11, wherein installing the heat spreader includes thermally connecting a portion of the heat spreader that extends laterally beyond the frame to a heat pipe that conducts heat away from the integrated circuit.

19. The method of claim 11, wherein the integrated circuit includes a central processing unit of an electronic device.

20. The method of claim 11, wherein installing the heat spreader includes pressing a portion of the heat spreader located within the frame into thermal contact with the integrated circuit.
